(19) United States
(12) Patent Application Publication
(10) Pub. No.: US 2024/0096841 A1
(43) Pub. Date: Mar. 21, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Ohguk KWON, Suwon-si (KR); Sunjae KIM, Suwon-si (KR); Seunghoon YEON, Suwon-si (KR); Seungryong OH, Suwon-si (KR); Huiyeong JANG, Suwon-si (KR)

(21) Appl. No.: 18/456,261

(22) Filed: Aug. 25, 2023

(30) Foreign Application Priority Data
Sep. 16, 2022 (KR) 10-2022-0117048

(51) Int. Cl. H01L 23/00; H01L 21/66; H01L 25/065

(52) U.S. Cl. CPC H01L 24/32; H01L 22/32; H01L 24/16; H01L 24/73; H01L 25/0657; H01L 2224/16148; H01L 2224/16227; H01L 2224/16238; H01L 2224/26145; H01L 2224/32145; H01L 2224/32225; H01L 2224/73204; H01L 2225/06513; H01L 2225/06517; H01L 2225/06541; H01L 2924/3841

(57) ABSTRACT

A semiconductor package includes a first semiconductor chip including a first substrate, a plurality of through electrodes penetrating the first substrate, and first bonding pads provided on one surface of the first substrate and electrically connected to the plurality of through electrodes, a second semiconductor chip including a second substrate, a second wiring layer provided on one surface of the second substrate and having redistribution pads and test pads, and second bonding pads on the redistribution pads, the second semiconductor chip being stacked on the first semiconductor chip via conductive bumps that are disposed between first and second bonding pads, an adhesive layer filling a space between the conductive bumps, and flow prevention structures in the adhesive layer on a test pad region where the test pads are disposed.

### PRIORITY STATEMENT

This application claims priority under 35 U.S.C. § 119 to Korean Patent Application No. 10-2022-0117048, filed on Sep. 16, 2022 in the Korean Intellectual Property Office (KIPO), the contents of which are herein incorporated by reference in their entirety.

### BACKGROUND

Example embodiments relate to a semiconductor package and a method of manufacturing the semiconductor package. More particularly, example embodiments relate to a multi-chip package including a plurality of different stacked chips and a method of manufacturing the same.

In manufacturing a system in package (SIP) including stacked chips, solder sweep may occur, resulting in a short circuit between adjacent micro bumps. Recently, since a pitch between the micro bumps is reduced in order to increase the number of input/output (I/O) terminals, there is a problem in that the risk of short circuit may increase.

### SUMMARY

Example embodiments provide a semiconductor package capable of preventing short circuit between bumps interposed between semiconductor chips to improve electrical reliability.

Example embodiments provide a method of manufacturing the semiconductor package.

According to example embodiments, a semiconductor package includes a first semiconductor chip including: a first substrate comprising a second surface; a plurality of through electrodes extending in the first substrate; and first bonding pads on the second surface of the first substrate, wherein the first bonding pads are electrically connected to the plurality of through electrodes; a second semiconductor chip including: a second substrate comprising a first surface; a second wiring layer on the first surface of the second substrate; redistribution pads in the second wiring layer; second bonding pads on the redistribution pads; first conductive bumps between the first bonding pads and the second bonding pads; and a test pad region between the first conductive bumps, wherein the test pad region comprises a test pad in the second wiring layer, wherein the second semiconductor chip is stacked on the first semiconductor chip via the first conductive bumps; an adhesive layer between the first semiconductor chip and the second semiconductor chip, wherein the adhesive layer is disposed between the first conductive bumps; and flow prevention structures in the adhesive layer, wherein the flow prevention structures are disposed in the test pad region.

According to example embodiments, a semiconductor package includes a first semiconductor chip including: a first substrate having a first surface and a second surface opposite to the first surface; a plurality of through electrodes penetrating the first substrate; first bonding pads on the first surface, wherein the first bonding pads are electrically connected to the plurality of through electrodes; and second bonding pads on the second surface, wherein the second bonding pads are electrically connected to the plurality of through electrodes; a second semiconductor chip including: a second substrate having a third surface and a fourth surface opposite to the third surface; a second wiring layer on the third surface of the second substrate; and third bonding pads on the second wiring layer, wherein the second semiconductor chip is on the second surface of the first substrate, the second wiring layer includes redistribution pads and test pads, and the third bonding pads are on the redistribution pads; conductive bumps between the first semiconductor chip and the second semiconductor chip and electrically connecting the second bonding pads and the third bonding pads; an adhesive layer between the first semiconductor chip and the second semiconductor chip, wherein the adhesive layer is in a space between the conductive bumps; and flow prevention structures in the adhesive layer, wherein the flow prevention structures overlap the test pads viewed from a plan view.

According to example embodiments, a semiconductor package includes a package substrate; a first semiconductor chip including a first substrate having a first surface and a second surface opposite to the first surface, a plurality of through electrodes penetrating the first substrate, first bonding pads on the first surface and electrically connected to the plurality of through electrodes, and second bonding pads on the second surface and electrically connected to the plurality of through electrodes, the first semiconductor chip being stacked on the package substrate via first conductive bumps that are on the first bonding pads; a second semiconductor chip including a second substrate having a third surface and a fourth surface opposite to the third surface, a second wiring layer having redistribution pads and test pads on the third surface of the second substrate, and third bonding pads on the redistribution pads, the second semiconductor chip being stacked on the first semiconductor chip via second conductive bumps that are on the third bonding pads, an adhesive layer between the first semiconductor chip and the second semiconductor chip to fill a space between the second conductive bumps; and flow prevention structures in the adhesive layer, wherein the flow prevention structures are arranged on at least one of the first semiconductor chip and the second semiconductor chip to overlap the test pads when viewed from a plan view.

According to example embodiments, in a method of manufacturing a semiconductor package, a first semiconductor chip including a first substrate, a plurality of through electrodes penetrating the first substrate, and first bonding pads provided on one surface of the first substrate and electrically connected to the plurality of through electrodes is provided. A second semiconductor chip including a second substrate, a second wiring layer provided on a front surface of the second substrate and having redistribution pads and test pads, and second bonding pads provided on the redistribution pads is provided. Flow prevention structures are formed on at least one of the first semiconductor chip and the second semiconductor chip to overlap the test pads when viewed from a plan view. Conductive bumps are formed on the second bonding pads of the second semiconductor chip. An adhesive layer is formed on the second wiring layer of the second semiconductor chip to cover the conductive bumps. The adhesive layer is on the first semiconductor chip so that the conductive bumps are disposed between the first bonding pads and the second bonding pads.

According to example embodiments, a semiconductor package may include a first semiconductor chip, a second semiconductor chip stacked on the first semiconductor chip via conductive bumps, an adhesive layer filling a space between the conductive bumps between the first semiconductor chip and the second semiconductor chip and attaching the first and second semiconductor chips, and flow prevention structures provided in the adhesive layer.

The flow prevention structures may be provided on a test pad region where the test pad of the second semiconductor chip is disposed. The flow prevention structures may be arranged on the test pad region between second conductive bumps.

Accordingly, the flow prevention structures may reduce the flowability of the adhesive layer during a thermal compression process using the adhesive layer to prevent a short circuit failure due to solder sweep between adjacent conductive bumps with a fine pitch. Thus, electrical reliability of the semiconductor package may be improved.

### BRIEF DESCRIPTION OF THE DRAWINGS

Example embodiments will be more clearly understood from the following detailed description taken in conjunction with the accompanying drawings. FIGS. 1 to 30 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating second conductive bumps and flow prevention structures on a second semiconductor chip in portion ‘A’ of FIG. 1.

FIGS. 4 to 15 are views illustrating a method of manufacturing a semiconductor package in accordance with example embodiments.

FIG. 16 is a cross-sectional view illustrating a semiconductor package in accordance with example embodiments.

FIG. 17 is an enlarged cross-sectional view illustrating portion ‘E’ in FIG. 16.

FIG. 18 is a plan view illustrating flow prevention structures on a first semiconductor chip in portion ‘E’ of FIG. 16.

FIGS. 19 to 26 are views illustrating a method of manufacturing a semiconductor package in accordance with example embodiments.

FIG. 27 is a cross-sectional view illustrating a semiconductor package in accordance with example embodiments.

FIG. 28 is an enlarged cross-sectional view illustrating portion ‘H’ in FIG. 27.

FIG. 29 is a cross-sectional view illustrating a semiconductor package in accordance with example embodiments.

FIG. 30 is an enlarged cross-sectional view illustrating portion ‘I’ in FIG. 29.

### DETAILED DESCRIPTION OF EXAMPLE EMBODIMENTS

Hereinafter, example embodiments will be explained in detail with reference to the accompanying drawings.

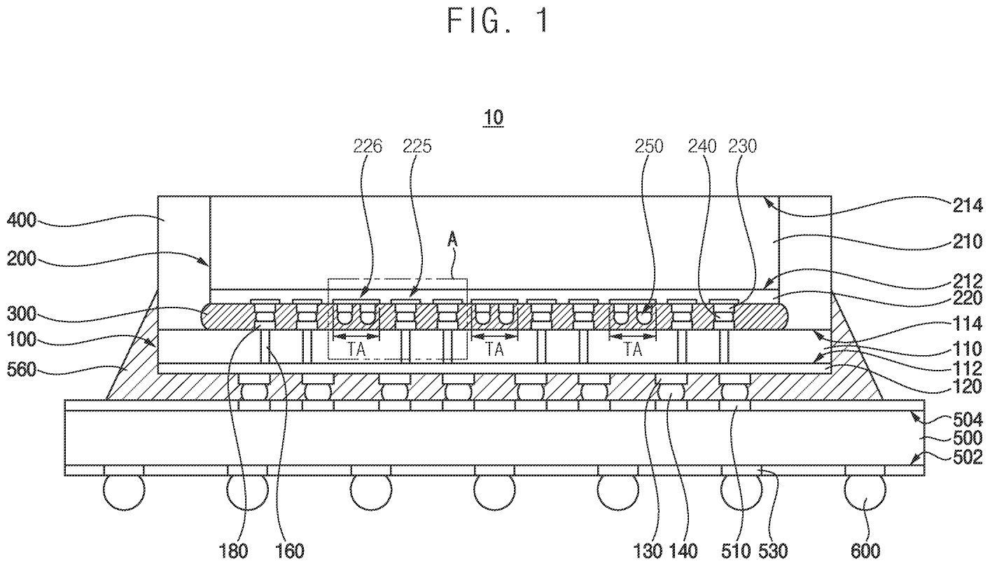

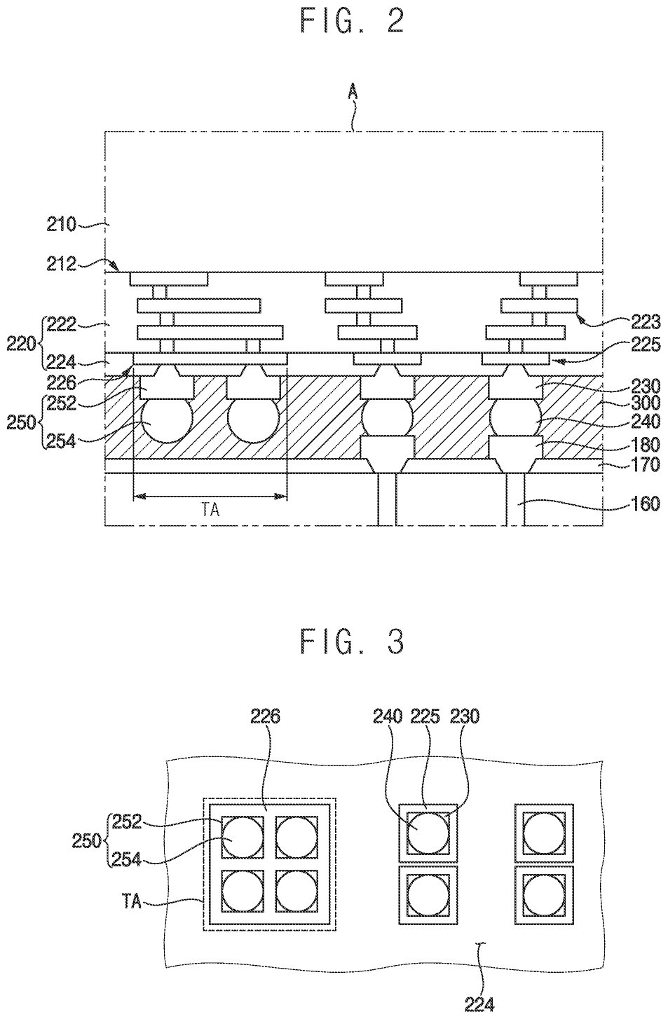

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating second conductive bumps and flow prevention structures on a second semiconductor chip in portion ‘A’ of FIG. 1.

Referring to FIGS. 1 to 3, a semiconductor package 10 may include a first semiconductor chip 100, a second semiconductor chip 200 stacked on the first semiconductor chip 100, an adhesive layer 300 interposed between the first and second semiconductor chips 100 and 200, and second flow prevention structures 250 provided in the adhesive layer 300. In addition, the semiconductor package 10 may further include a sealing member 400, a package substrate 500 on which the stacked first and second semiconductor chips 100 and 200 are mounted, and external connection members 600 provided on a lower surface of the package substrate 500.

In addition, the semiconductor package 10 may be a multi-chip package (MCP) including different types of semiconductor chips. The semiconductor package 10 may be a system in package (SIP) including a plurality of semiconductor chips stacked or arranged in one package to perform all or most of the functions of an electronic system.

The semiconductor package 10 may include the first semiconductor chip 100 as a logic chip and the second semiconductor chip 200 as a memory chip, sequentially stacked. The first semiconductor chip 100 may be a logic chip including a logic circuit. The logic chip may be a controller that controls memory devices of the second semiconductor chip. The first semiconductor chip 100 may be, for example, a processor chip serving as a host, such as an application-specific integrated circuit (ASIC), an application processor (AP), a central processing unit (CPU), a graphics processing unit (GPU), or a system on chip (SOC), but not limited thereto. The second semiconductor chip 200 may include a dynamic random access memory (DRAM), a static random access memory (SRAM), but not limited thereto.

In this embodiment, the semiconductor package 10 as a multi-chip package is illustrated as including two stacked first and second semiconductor chips 100 and 200. However, it is not limited thereto, and for example, the semiconductor package 10 may include more than two (e.g., 4, 8, 12, or 16) stacked semiconductor chips.

In example embodiments, the first semiconductor chip 100 may include a first substrate 110, a first wiring layer 120, a plurality of first bonding pads 130, a plurality of through electrodes 160 and a plurality of second bonding pads 180. In addition, the first semiconductor chip 100 may further include first conductive bumps 140 as first conductive connection members respectively provided on the first bonding pads 130. The first semiconductor chip 100 may be mounted on the package substrate 500 via the first conductive bumps 140. For example, the first conductive bumps 140 may include solder bumps.

The first substrate 110 may have a first surface 112 and a second surface 114 opposite to each other. The first surface 112 of the first substrate 110 may be an active surface, and the second surface 114 of the first substrate 110 may be an inactive surface. Circuit patterns and cells may be formed on the first surface 112 of the first substrate 110. For example, the first substrate 110 may be a single crystal silicon substrate. The circuit patterns may include, for example, transistors, capacitors, diodes, and the like. The circuit patterns may constitute circuit elements. Accordingly, the first semiconductor chip 100 may be a semiconductor device in which a plurality of the circuit elements is formed.

The first wiring layer 120 may be provided on the first surface 112 of the first substrate 110, that is, the active surface. The first wiring layer 120 may include a first metal wiring layer 122 (see 122 in FIG. 12) on the first surface 112 of the first substrate 110 and first passivation layer 124 (see 124 in FIG. 12) on the first metal wiring layer 122. The first metal wiring layer 122 may include first upper wirings 123 (see 123 in FIG. 12). The first metal wiring layer 122 may include a plurality of insulating layers. In addition, first redistribution pads 125 (see 125 in FIG. 12) may be provided on an outermost insulating layer of the first metal wiring layer 122 (e.g., on a lower surface of the first metal wiring layer 122), and the first bonding pads 130 may be provided on the first redistribution pads 125.

The through electrode 160 may vertically penetrate the first substrate 110 from the first surface 112 to the second surface 114 of the first substrate 110. The through electrode 160 may be a through silicon via (TSV). A first end portion (e.g., lower end portion) of the through electrode 160 may contact the first upper wiring 123. However, the embodiment of the through electrode 160 is not limited thereto. For example, the through electrode 160 may further extend through the first wiring layer 120 and may directly contact the first bonding pad 130.

The first backside insulation layer 170 may be provided on the second surface 114 of the first substrate 110, that is, a backside surface. The second bonding pads 180 may be provided on the first backside insulation layer 170. The second bonding pad 180 may be disposed on an exposed surface of the through electrode 160. Accordingly, the first and second bonding pads 130 and 180 may be electrically connected to each other through the through electrode 160. The first and second bonding pads 130 and 180 may be arranged in respective arrays on the upper surface (e.g., second surface 114 of the first substrate 110) and lower surface (e.g., first surface 112 of the first substrate 110) of the first semiconductor chip 100, and the through electrodes 160 may be provided in the first substrate 110 to be arranged in an array form. For example, the arrangement of the through electrodes 160 may (e.g., via arrangement) correspond to the pad arrangement of the second bonding pads 180.

In example embodiments, the second semiconductor chip 200 may include a second substrate 210, a second wiring layer 220 and a plurality of third bonding pads 230. In addition, the second semiconductor chip 200 may further include second conductive bumps 240 as second conductive connection members respectively provided on the third bonding pads 230. The second semiconductor chip 200 may be mounted on the first semiconductor chip 100 via the second conductive bumps 240. For example, the second conductive bumps 240 may include solder bumps.

The second substrate 210 may have a first surface 212 and a second surface 214 opposite to each other. The first surface 212 of the second substrate 210 may be an active surface, and the second surface 214 of the second substrate 210 may be an inactive surface. Circuit elements may be formed on the first surface 212 of the second substrate 210. The circuit element may include a plurality of memory devices. Examples of the memory device may include a volatile semiconductor memory device and/or a non-volatile semiconductor memory device. An insulation interlayer covering the circuit elements may be formed on the first surface 212 of the second substrate 210.

The second wiring layer 220 may include a second metal wiring layer 222 and a protective layer 224 sequentially stacked on the first surface 212 of the second substrate 210. The second metal wiring layer 222 may include a plurality of insulating layers, second upper wirings 223 in the insulating layers, and second redistribution pads 225 and test pads 226 as uppermost wirings. The protective layer 224 may be formed on the second metal wiring layer 222 and may cover the second redistribution pads 225 and the test pads 226.

The second redistribution pads 225 and the test pads 226 may be electrically connected to the circuit elements through the second upper wirings 223 and contact plugs in the insulating layers of the second metal wiring layer 222. The third bonding pad 230 may be provided on at least a portion of the second redistribution pad 225. The third bonding pad 230 may be electrically connected to the second redistribution pad 225.

The test pad 226 may be used as a test pad in an electrical die sorting (EDS) process. After performing the EDS process, the protective layer 224 may be formed on the second metal wiring layer 222 to cover the test pads 226.

The test pads 226 may be respectively disposed in test pad regions TA. The test pad regions TA may be positioned between pad regions where the second redistribution pads 225 are disposed respectively. The test pad region TA may have a larger planar area than that of the pad region or the second redistribution pads 225. Alternatively, the test pad region TA may have substantially the same planar area as the pad region.

The sizes and thicknesses of the first and second semiconductor chips, the number, size, arrangement, etc. of the insulating layers of the wiring layer, the upper wirings, the redistribution pads and the test pads are provided as examples, and it will be understood that it is not limited thereto. For example, the first semiconductor chip 100 may have a thickness in a range of 50 μm to 120 μm, and the second semiconductor chip 200 may have a thickness in a range of 40 μm to 700 μm.

The second conductive bumps 240 may be respectively provided on the third bonding pads 230. A pitch between the second conductive bumps 240 may be within a range of 15 μm to 35 μm. For example, the second conductive bump 240 of the second semiconductor chip 200 may be in contact with (e.g., bonded to) the second bonding pad 180 of the first semiconductor chip 100 by a flip chip bonding process. Accordingly, the third bonding pad 230 of the second semiconductor chip 200 may be electrically connected to the second bonding pad 180 of the first semiconductor chip 100 by the second conductive bump 240.

In example embodiments, the adhesive layer 300 may be provided (e.g., to fill a space) between the second conductive bumps 240 between the first semiconductor chip 100 and the second semiconductor chip 200. For example, the adhesive layer 300 may include a non-conductive film (NCF), but not limited thereto.

For example, the second semiconductor chip 200 and the first semiconductor chip 100 may be attached to each other by a thermal compression process using the non-conductive film. In the thermal compression process, the non-conductive film may be liquefied and have fluidity, and may flow between the second conductive bumps 240 between the second semiconductor chip 200 and the first semiconductor chip 100, and then may be cured to fill the space between the second conductive bumps 240. A portion of the cured adhesive layer 300 may protrude from a side surface of the second semiconductor chip 200.

In example embodiments, the second flow prevention structures 250 may be provided in the adhesive layer 300 in the test pad region TA. When viewed from a plan view, the second flow prevention structure 250 may be disposed to overlap each of the test pads 226. One or more second flow prevention structures 250 may be provided in one test pad region TA.

The second flow prevention structure 250 may include a dummy pad 252 provided on the test pad 226 and a dummy bump 254 provided on the dummy pad 252. As illustrated in FIG. 3, four dummy pads 252 may be disposed on one test pad 226, and four dummy bumps 254 may be respectively disposed on the four dummy pads 252. For example, the dummy pads 252 and the dummy bumps 254 may not have a function in the operation of the first and second semiconductor chips 100 and 200.

For example, the third bonding pads 230 and the dummy pads 252 may be formed together by a plating process. For example, the third bonding pad 230 and the dummy pad 252 may include copper (Cu), aluminum (Al), tungsten, nickel (Ni), molybdenum (Mo), gold (Au), silver (Ag), chromium (Cr), tin (Sn), titanium (Ti), and/or the like. The third bonding pads 230 and the dummy pads 252 may include the same (e.g., metal) material. The second conductive bumps 240 and the dummy bumps 254 may be formed together by a plating process. The second conductive bumps 240 and the dummy bumps 254 may include the same material.

The second conductive bumps 240 and the dummy bumps 254 may include solder bumps. The dummy bump 254 may have a diameter the same as a diameter of the second conductive bump 240. A height of the second flow prevention structure 250 from the test pad 226 may be substantially the same as a height of the second conductive bump 240 from the second redistribution pad 225. For example, a height of the dummy bump 254 from the test pad 226 may be substantially the same as a height of the second conductive bump 240 may be from the second redistribution pad 225.

In example embodiments, a portion of the protective layer 224 may be removed to expose at least a portion of the test pad 226, and the dummy pad 252 may be provided on the exposed portion of the test pad 226. In this case, the dummy pad 252 may be electrically connected to the test pad 226.

In some embodiments, a portion of the protective layer 224 on the test pad 226 may not be removed. Accordingly, the test pad 226 may be covered by the protective layer 224 not to be exposed. In this case, the dummy pad 252 may be formed on the protective layer 224, and the dummy pad 252 may be electrically insulated from the test pad 226.

In the thermal compression process using the non-conductive film, a solder sweep may occur due to the flow of the non-conductive film. The second flow prevention structure 250 having the dummy pad 252 and the dummy bump 254 may be formed in the test pad region TA between the second conductive bumps 240 to prevent a solder sweep due to the flow of the non-conductive film, to thereby prevent a short circuit failure due to the solder sweep.

In example embodiments, the sealing member 400 may cover the second semiconductor chip 200 on the first semiconductor chip 100. The sealing member 400 may cover the side surface of the second semiconductor chip 200. An upper surface, that is, backside surface of the second semiconductor chip 200 may be exposed by the sealing member 400. For example, the sealing member 400 may include a thermosetting resin or the like.

In example embodiments, the package substrate 500 may be a substrate having an upper surface 504 and a lower surface 502 opposite to each other. For example, the package substrate 500 may be a printed circuit board (PCB). The printed circuit board may be a multilayer circuit board having vias and various circuits therein.

The first semiconductor chip 100 may be mounted on the package substrate 500 via the first conductive bumps 140. The first surface 112 of the first substrate 110 of the first semiconductor chip 100 may face the package substrate 500. The first conductive bump 140 of the first semiconductor chip 100 may be bonded to a substrate pad 510 on the upper surface 504 of the package substrate 500. A planar area of the first semiconductor chip 100 may be smaller than a planar area of the package substrate 500. When viewed from a plan view, the first semiconductor chip 100 may be disposed within the package substrate 500.

In example embodiments, an underfill member 560 may be interposed between the first semiconductor chip 100 and the package substrate 500. For example, the underfill member 560 may include an epoxy material to reinforce a gap between the first semiconductor chip 100 and the package substrate 500.

External connection pads 530 may be provided on the lower surface 502 of the package substrate 500, and the external connection members 600 may be respectively disposed on the external connection pads 530. For example, the external connection member 600 may be a solder ball. The semiconductor package 10 may be mounted on a module substrate (not illustrated) via the solder balls (e.g., the external connection member 600) to form a memory module.

As mentioned above, the semiconductor package 10 may include the first semiconductor chip 100, the second semiconductor chip 200 stacked on the first semiconductor chip 100 via the second conductive bumps 240, the adhesive layer 300 filling the space between the second conductive bumps 240 between the first semiconductor chip 100 and the second semiconductor chip 200 and attaching the first and second semiconductor chips 100 and 200, and the second flow prevention structures 250 provided in the adhesive layer 300.

The second flow prevention structure 250 may be provided in the test pad region TA where the test pad 226 of the second semiconductor chip 200 is disposed. The second flow prevention structure 250 may be formed in the test pad region TA between the second conductive bumps 240.

Accordingly, the second flow prevention structure 250 may reduce the flowability of the adhesive layer 300 during the thermal compression process and thereby may prevent a short circuit failure due to solder sweep between adjacent second conductive bumps 240 with a fine pitch. Thus, electrical reliability of the semiconductor package 10 may be improved.

Hereinafter, a method of manufacturing the semiconductor package 10 of FIG. 1 will be described.

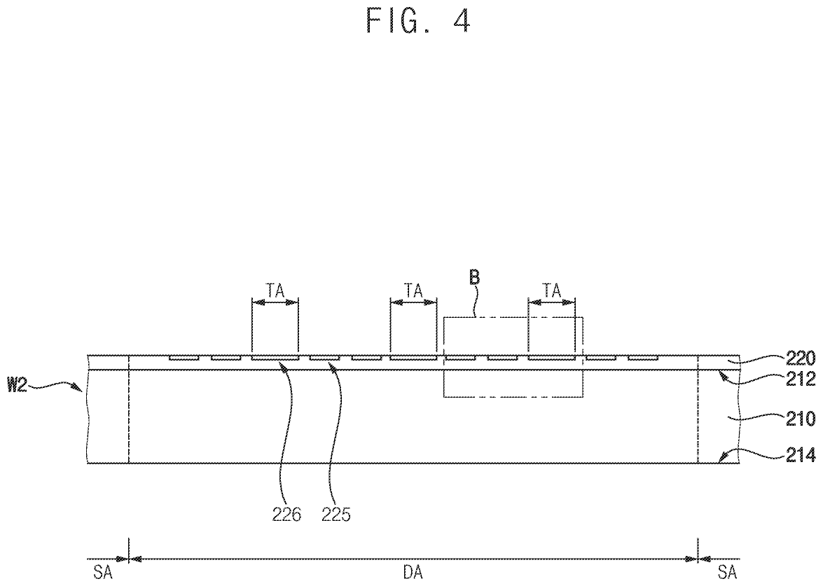

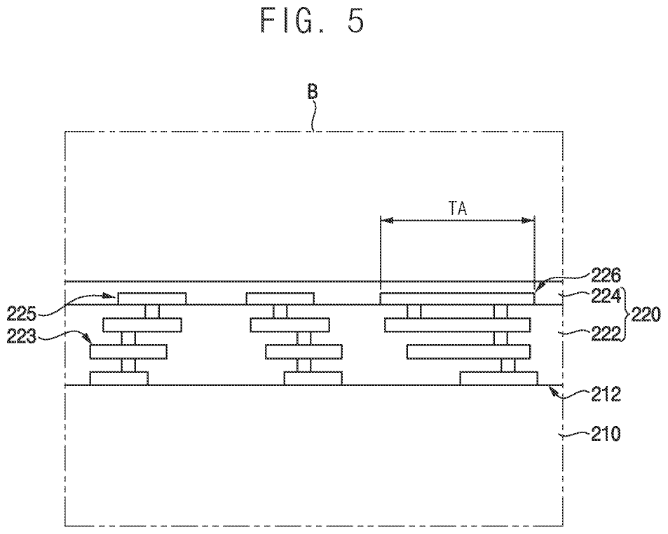

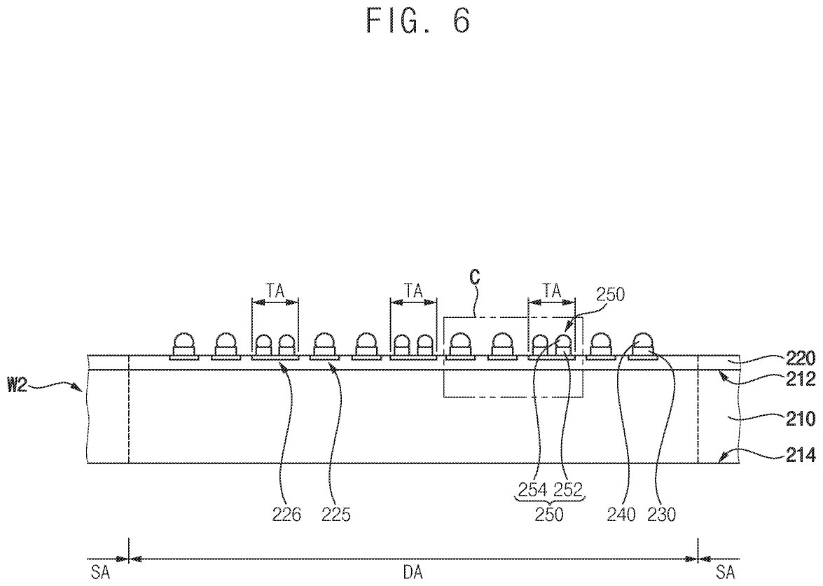

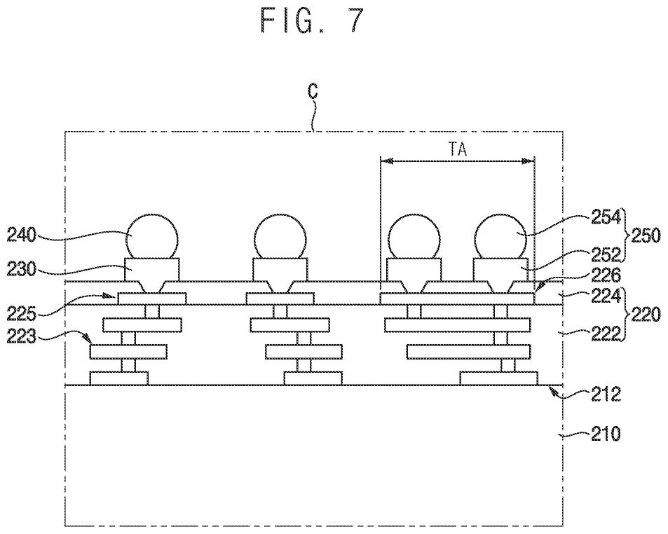

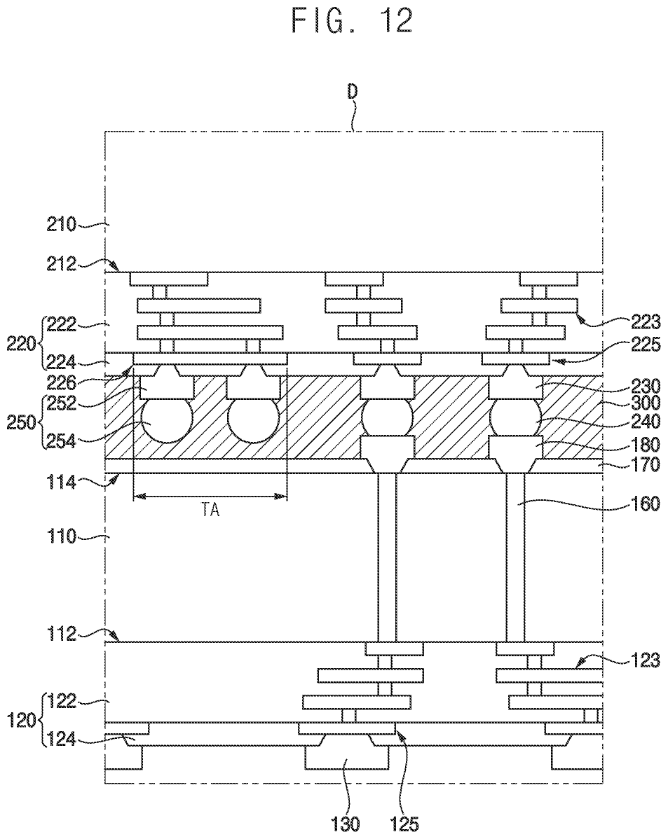

FIGS. 4 to 15 are views illustrating a method of manufacturing a semiconductor package in accordance with example embodiments. FIG. 5 is an enlarged cross-sectional view illustrating portion ‘B’ in FIG. 4. FIG. 7 is an enlarged cross-sectional view illustrating portion ‘C’ in FIG. 6. FIG. 12 is an enlarged cross-sectional view illustrating portion ‘D’ in FIG. 11.

Referring to FIGS. 4 and 5, a second wafer W2, including a plurality of second semiconductor chips (dies) formed therein, may be provided.

In example embodiments, the second wafer W2 may include a second substrate 210 having a first surface 212 and a second surface 214 opposite to the first surface 212. The second substrate 210 may include a die region DA and a scribe lane region SA surrounding the die region DA. The second substrate 210 may be cut along the scribe lane region SA that divides the plurality of die regions DA of the second wafer W2 by a following sawing process to be individualized into a plurality of second semiconductor chips (e.g., second semiconductor chip 200).

Circuit elements may be formed in the die region DA on the first surface 212 of the second substrate 210. The circuit element may include a plurality of memory devices. Examples of the memory device may be a volatile semiconductor memory device and a non-volatile semiconductor memory device. Examples of the volatile semiconductor memory device may be DRAM, SRAM, and the like. Examples of the non-volatile semiconductor memory device may be erasable programmable read-only memory (EPROM), electrically erasable programmable read-only memory (EEPROM), Flash EEPROM, and the like.

For example, the second substrate 210 may include silicon, germanium, silicon-germanium, and/or III-V compounds, such as GaP, GaAs, and GaSb. In some embodiments, the second substrate 210 may be a silicon-on-insulator (SOI) substrate, or a germanium-on-insulator (GOI) substrate, but not limited thereto.

The circuit elements may include, for example, transistors, capacitors, and/or wiring structures. The circuit elements may be formed on the first surface 212 of the second substrate 210 by performing a Fab process called a Front End of Line (FEOL) process for manufacturing semiconductor devices. A surface of the second substrate 210 on which the FEOL process is performed may be referred to as a front side surface (e.g., first surface 212) of the second substrate 210, and a surface opposite to the front side surface may be referred to as a backside surface (e.g., second surface 214 of the second substrate 210). An insulation interlayer covering the circuit elements may be formed on the first surface 212 of the second substrate 210.

In example embodiments, the second wafer W2 may include a second wiring layer 220 provided on the second substrate 210. The second wiring layer 220 may include a second metal wiring layer 222 and a protective layer 224 sequentially stacked on the second substrate 210. The second wiring layer 220 may be formed by performing a wiring process called a back-end-of-line (BEOL) process.

The second metal wiring layer 222 may include a plurality of insulating layers, second upper wirings 223 in the insulating layers, and second redistribution pads 225 and test pads 226 as uppermost wirings. The protective layer 224 may be formed on the second metal wiring layer 222 and may cover the second redistribution pads 225 and the test pads 226.

For example, the insulating layers in the second metal wiring layer 222 may be formed of oxide such as silicon oxide, carbon-doped oxide, and/or fluorine-doped oxide, but not limited thereto. The protective layer 224 may include a passivation layer including, for example, nitride such as silicon nitride (SiN). In some embodiments, the passivation layer may include an organic passivation layer, including an oxide layer, and an inorganic passivation layer, including a nitride layer, sequentially stacked. The second upper wirings 223, the second redistribution pads 225 and the test pads 226 may include a metal material such as aluminum (Al) and/or copper (Cu), but not limited thereto.

The second redistribution pads 225 and the test pads 226 may be electrically connected to the circuit elements through the second upper wirings 223 and contact plugs in the insulation interlayer. As will be described later, a bonding pad may be formed on at least a portion of the second redistribution pad 225 to be electrically connected to an external device. The test pad 226 may be used as a test pad in an electrical die sorting (EDS) process. The EDS process may be a process of selecting good products by checking each chip (die) formed by the previous processes through various electrical property tests in a wafer state. During the EDS process, fine pins of a probe card may contact the test pads 226 to transmit test signals and detect electrical signals therefrom. After performing the EDS process, the passivation layer may be formed on the second metal wiring layer 222 to cover the test pads 226.

The test pads 226 may be respectively disposed in test pad regions TA. The test pad regions TA may be positioned between pad regions where the second redistribution pads 225 are disposed respectively. The test pad region TA may have a larger planar area than that of the pad region or the second redistribution pad 225. Alternatively, the test pad region TA may have substantially the same planar area as the pad region.

The number, size, arrangement, etc. of the insulating layers, the upper wirings, the redistribution pads and the test pads of the wiring layer are provided as examples, and it will be understood that it is not limited thereto.

Referring to FIGS. 6 and 7, third bonding pads 230 may be formed on the second redistribution pads 225 on the second wiring layer 220 respectively, and second conductive bumps 240 may be formed on the third bonding pads 230 respectively. In addition, second flow prevention structures 250 may be respectively formed on the test pads 226 on the second wiring layer 220.

In example embodiments, portions of the protective layer 224 may be removed to expose portions of the second redistribution pads 225 and/or portions of the test pads 226.

For example, a photoresist layer may be formed on the protective layer 224, an exposure process may be performed to form a photoresist pattern having openings that expose portions of the protective layer 224, and the photoresist pattern may be used as an etching mask to partially remove the protective layer 224.

Then, the third bonding pads 230 may be formed on the exposed portions of the second redistribution pads 225 and dummy pads 252 may be formed on the exposed portions of the test pads 226.

For example, the third bonding pads 230 and the dummy pads 252 may be formed together by a plating process. For example, the third bonding pad 230 and the dummy pad 252 may be formed of copper (Cu), aluminum (Al), tungsten, nickel (Ni), molybdenum (Mo), gold (Au), or silver (Ag), chromium (Cr), tin (Sn), and/or titanium (Ti). The third bonding pads 230 and the dummy pads 252 may include the same metal material.

Although it is not illustrated in the figures, a plating layer may be formed on the third bonding pad 230. The plating layer may include a metal different from that of the third bonding pad 230. For example, the plating layer may include gold (Au). The plating layer may have a thickness of 0.05 μm to 0.2 μm.

A plurality of the dummy pads 252 may be formed on one test pad 226. For example, four dummy pads 252 may be formed on one test pad 226. Alternatively, one dummy pad 252 may be formed on one test pad 226.

In some embodiments, a portion of the protective layer 224 on the test pads 226 may not be removed. Accordingly, the test pads 226 may be covered by the protective layer 224 not to be exposed. In this case, the dummy pads 252 may be respectively formed on the protective layer 224 on the test pads 226.

Then, the second conductive bumps 240 may be respectively formed on the third bonding pads 230. In addition, dummy bumps 254 may be respectively formed on the dummy pads 252.

For example, the second conductive bumps 240 and the dummy bumps 254 may be formed together by a plating process. In particular, a seed layer may be formed on the third bonding pads 230 and the dummy pads 252 on the second wiring layer 220, and a photoresist pattern having openings that exposing portions of the seed layer may be formed. After filling the openings of the photoresist pattern with a conductive material, the photoresist pattern may be removed and a reflow process may be performed to form the second conductive bumps 240 and the dummy bumps 254. Alternatively, the second conductive bumps 240 and the dummy bumps 254 may be formed by a screen printing method or a deposition method, but not limited thereto. The second conductive bumps 240 and the dummy bumps 254 may include solder bumps.

A height of the second flow prevention structure 250 (e.g., a height of the dummy bump 254) from the test pad 226 may be substantially the same as a height of the second conductive bump 240 from the second redistribution pad 225. A pitch between the second conductive bumps 240 may be within a range of 15 μm to 35 μm.

Thus, the second flow prevention structure 250 having the dummy pad 252 and the dummy bump 254 sequentially stacked in the test pad region TA may be formed. When viewed from a plan view, the second flow prevention structure 250 may be disposed to overlap the test pad 226. A plurality of the second flow prevention structures 250 may be formed on one test pad 226.

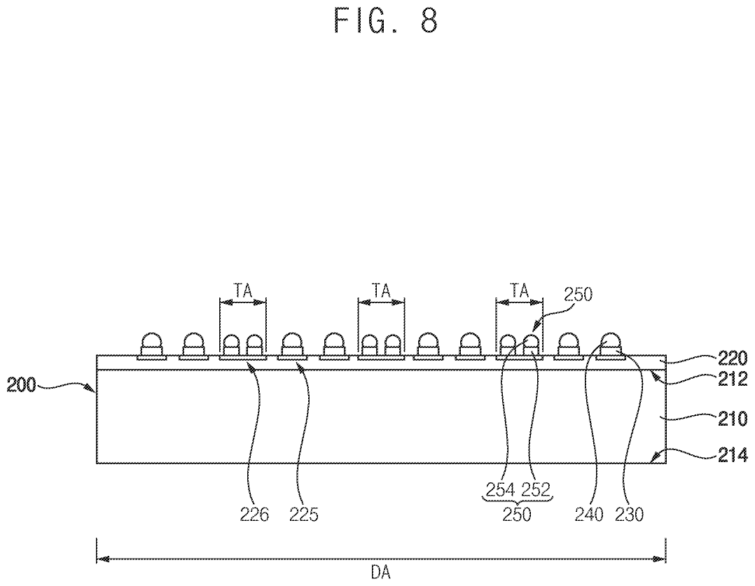

Referring to FIG. 8, the second wafer W2 may be cut along the scribe lane region SA to form an individualized second semiconductor chip 200. The second wafer W2 may be cut by a sawing process, but not limited thereto.

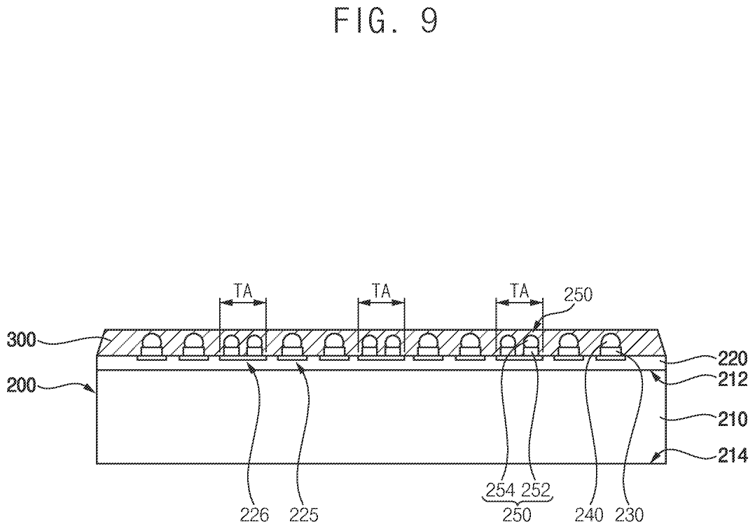

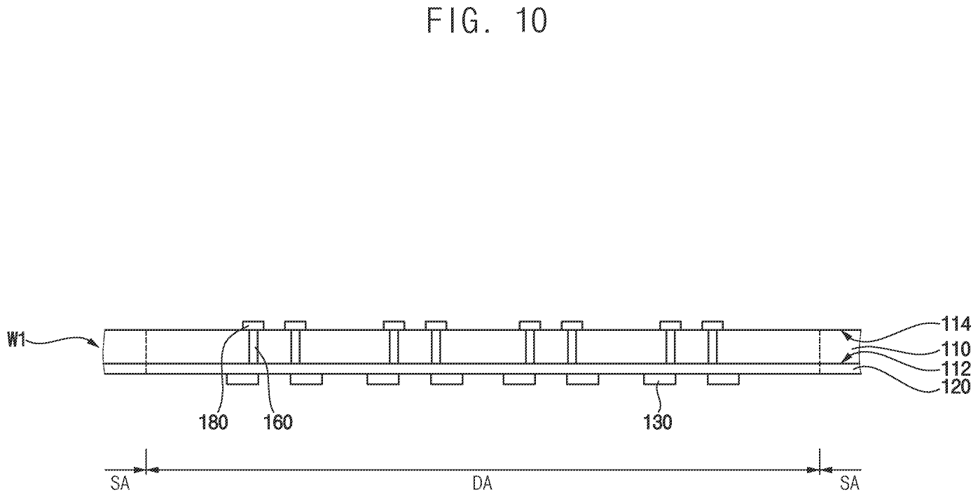

Referring to FIG. 9, an adhesive layer 300 may be attached to the second semiconductor chip 200 in order to adhere the second semiconductor chip 200 to a first wafer, which will be described later. The adhesive layer 300 may be formed on the second wiring layer 220 to cover the second conductive bumps 240 and the second flow prevention structures 250.

For example, the adhesive layer 300 may include a thermosetting resin. The adhesive layer 300 may include a non-conductive film (NCF), but not limited thereto.

In some embodiments, the adhesive layer 300 may be formed on the second wiring layer 220 of the second wafer W2 before performing the sawing process.

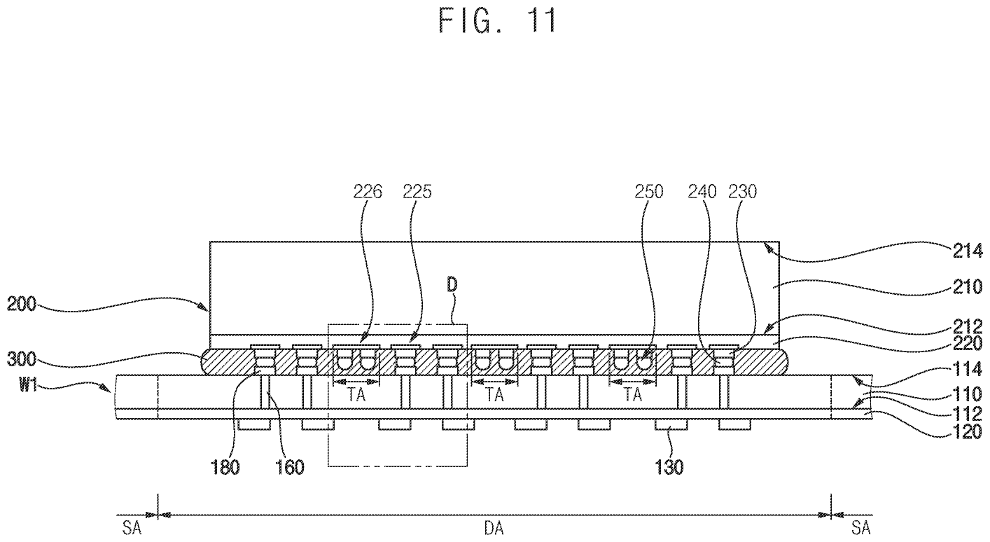

Referring to FIGS. 10 to 12, the second semiconductor chip 200 may be stacked on a first wafer W1. The second semiconductor chip 200 may be mounted on the first wafer W1 via the second conductive bumps 240.

As illustrated in FIG. 10, the first wafer W1 including a plurality of first semiconductor chips (dies) formed therein, may be provided.

In example embodiments, the first wafer W1 may include a first substrate 110 having a first surface 112 and a second surface 114 opposite to the first surface 112. The first substrate 110 may include a die region DA and a scribe lane region SA surrounding the die region DA. The first substrate 110 may be cut along the scribe lane region SA that divides the plurality of die regions DA of the first wafer W1 by a following sawing process to be individualized into a plurality of first semiconductor chips 100 (see 100 in FIG. 1).

Circuit elements may be formed in the die region DA on the first surface 112 of the first substrate 110. The first semiconductor chip 100 may be a logic chip including a logic circuit. The logic chip may be a controller that controls the memory devices of the second semiconductor chip 200 (see 200 in FIG. 1). The first semiconductor chip 100 may be an ASIC serving as a host such as a CPU, GPU, or SOC, or a processor chip such as an application processor (AP).

The circuit elements may include, for example, transistors, capacitors, wiring and/or structures. The circuit elements may be formed on the first surface 112 of the first substrate 110 by performing a Fab process called a front end of line (FEOL) process for manufacturing semiconductor devices. A surface of the first substrate 110 on which the FEOL process is performed may be referred to as a front side surface (e.g., first surface 112) of the first substrate 110, and a surface opposite to the front side surface may be referred to as a backside surface (e.g., second surface 114) of the first substrate 110. An insulation interlayer covering the circuit elements may be formed on the first surface 112 of the first substrate 110.

The first wafer W1 may include a first wiring layer 120 provided on the first surface 112 of the first substrate 110, first bonding pads 130 provided on the first wiring layer 120, second bonding pads 180 provided on the second surface 114 of the first substrate 110, and through electrodes 160 penetrating the first substrate 110 and electrically connecting the first and second bonding pads 130 and 180 to each other.

As illustrated in FIGS. 11 and 12, the second semiconductor chip 200 may be stacked on the first wafer W1 using a substrate support system (WSS). The second semiconductor chips 200 may be disposed on the first wafer W1 to correspond to the die regions DA, respectively. The second semiconductor chip 200 may be attached on the first wafer W1 using the adhesive layer 300. The second semiconductor chip 200 may be arranged such that the first surface 212 of the second substrate 210 faces the first wafer W1.

A thermal compression process may be performed at a predetermined temperature (eg, about 400° C. or less) to attach the second semiconductor chip 200 on the first wafer W1. By the thermal compression process, the second semiconductor chip 200 and the first wafer W1 may be bonded to each other. The embodiments of the boding method, however, are not limited to the above noted thermal compression process.

In the thermal compression process, the non-conductive film, which will be the adhesive layer 300 by the following processes, may be liquefied and has fluidity, and may flow between the second semiconductor chip 200 and the first wafer W1. The nonconductive film having fluidity may flow between the second conductive bumps 240 and then be cured to fill a space between the second conductive bumps 240. A portion of the cured adhesive layer 300 may protrude from a side surface of the second semiconductor chip 200.

At this time, a solder sweep may occur due to the flow of the non-conductive film. In case of a fine pitch between the second conductive bumps 240, when sweeps occur in opposite directions, adjacent bumps may come into contact with each other, resulting in a short circuit failure. In particular, since the second conductive bumps 240 are not formed on the test pad region TA, the possibility of occurrence of the short circuit failure due to the solder sweep may increase. The second flow prevention structure 250 having the dummy pad 252 and the dummy bump 254 may be formed in the test pad region TA between the second conductive bumps 240. Accordingly, a solder sweep due to the flow of the non-conductive film may be prevented (reduced) to thereby prevent a short circuit failure.

The second conductive bump 240 of the second semiconductor chip 200 may be bonded to the second bonding pad 180 of the first semiconductor chip 100 by the thermal compression process. The embodiments of the boding method, however, are not limited to the above noted thermal compression process. The second bonding pad 180 may be electrically connected to the first bonding pad 130 by the through electrode 160, the first upper wirings 123 of the first wiring layer 120 and the first redistribution pad 125.

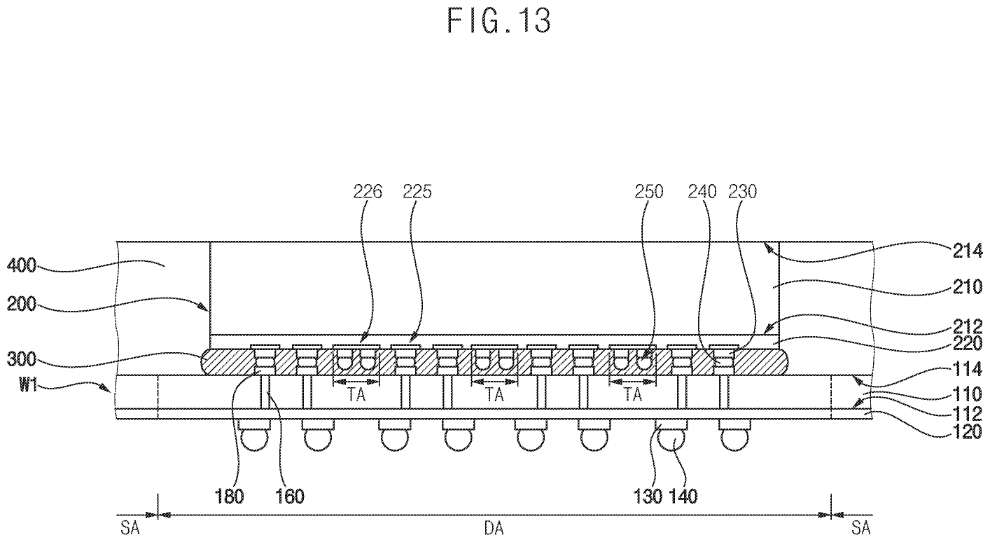

Referring to FIG. 13, a sealing member 400 may be formed on the first wafer W1. The sealing member 400 may cover a portion (e.g., sidewall) of the second semiconductor chip 200.

In example embodiments, the sealing member 400 may be formed to fill spaces between the second semiconductor chips 200 on the first wafer W1. The sealing member 400 may be formed to surround the second semiconductor chips 200. An upper surface, that is, a backside surface of the second semiconductor chip 200 may be exposed by the sealing member 400. The sealing member 400 may be formed by a dispensing process or a spin coating process, but not limited thereto. For example, the sealing member 400 may include a thermosetting resin or the like.

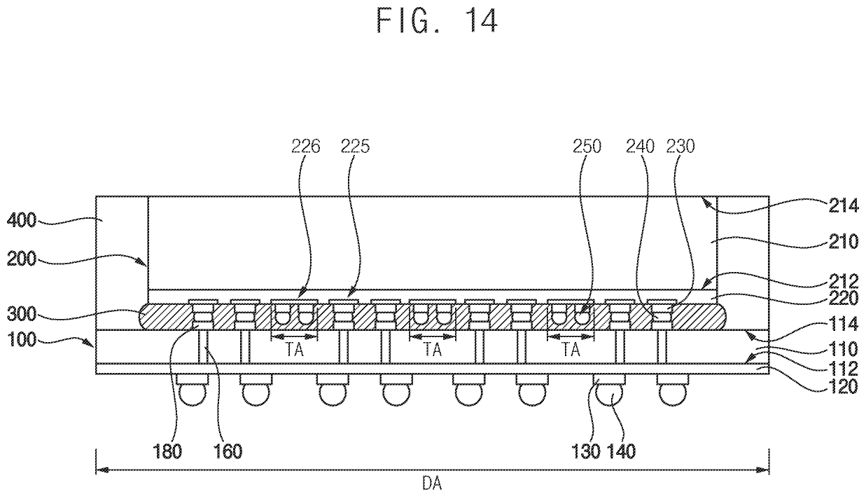

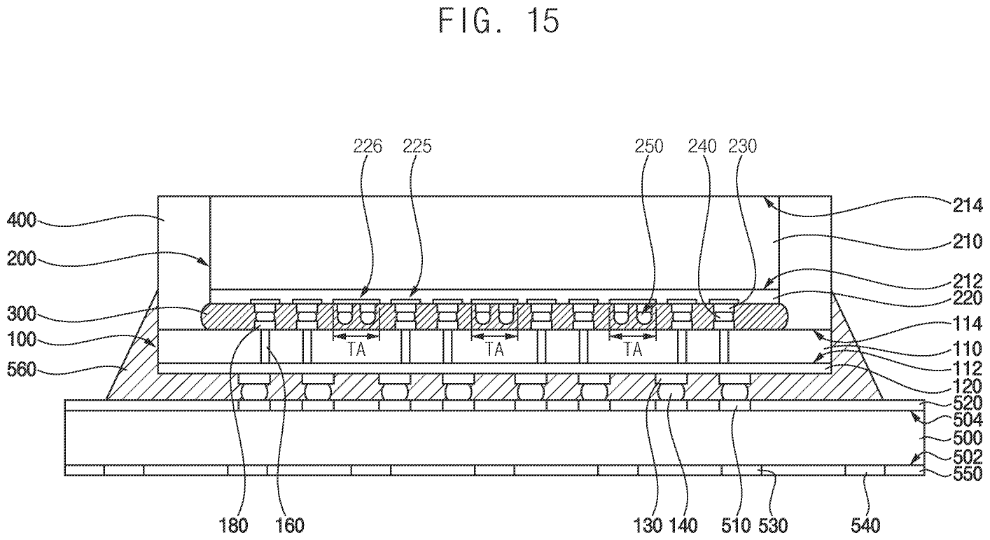

Referring to FIG. 14, first conductive bumps 140 may be formed on the first bonding pads 130 of the first wafer W1, and the first wafer W1 and the sealing member 400 may be cut along the scribe lane region SA to form an individualized first semiconductor chip 100. The second wafer W2 may be cut by a sawing process, but not limited thereto. Thus, a stack package in which the second semiconductor chip 200 is stacked on the first semiconductor chip 100 may be formed.

Processes the same as or similar to the processes described with reference to FIGS. 6 and 7 may be performed to form the first conductive bumps 140 on the first bonding pads 130 of the first wafer W1.

Referring to FIG. 15, the stack package may be mounted on a package substrate 500.

In example embodiments, the first semiconductor chip 100 may be mounted on the package substrate 500 via the first conductive bumps 140. The first surface 112 of the first substrate 110 of the first semiconductor chip 100 may face the package substrate 500. The first conductive bump 140 of the first semiconductor chip 100 may be bonded to a substrate pad 510 on an upper surface 504 of the package substrate 500.

Then, an underfill member 560 may be underfilled between the first semiconductor chip 100 and the package substrate 500. While moving a dispenser nozzle along a side of the first semiconductor chip 100, an underfill solution may be dispensed between the first semiconductor chip 100 and the package substrate 500, and the underfill solution may be cured to form the underfill member 560.

For example, the underfill member 560 may include an epoxy material, but not limited thereto, to reinforce a gap between the first semiconductor chip 100 and the package substrate 500.

Then, external connection members 600 (see FIG. 1) may be formed on external connection pads 530 on a lower surface 502 of the package substrate 500 to complete a semiconductor package 10 (see FIG. 1).

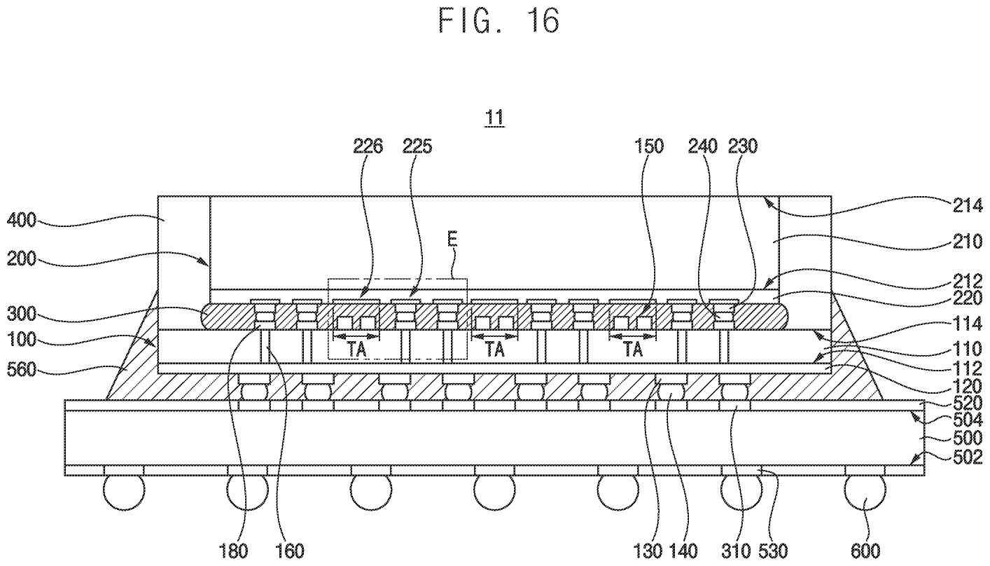

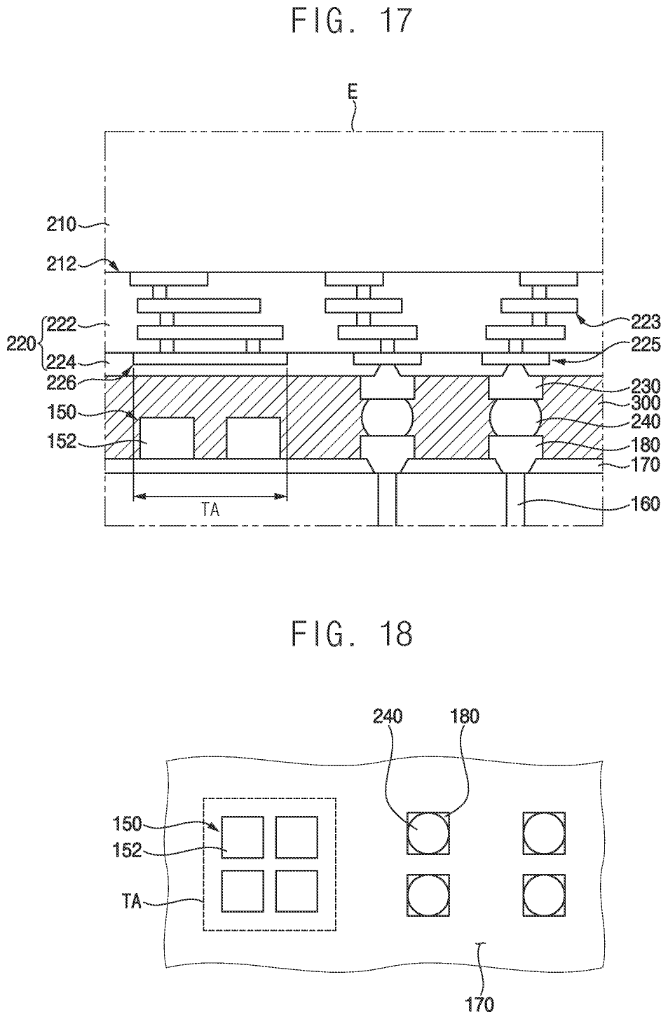

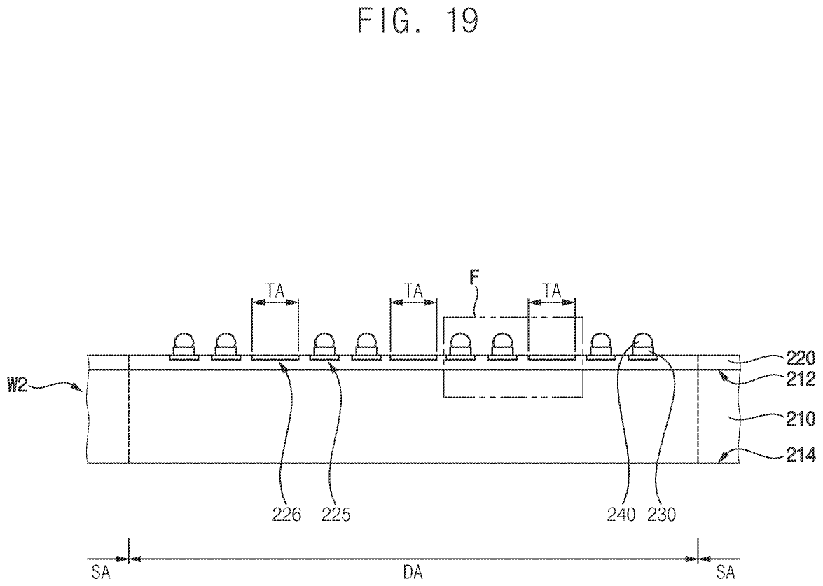

FIG. 16 is a cross-sectional view illustrating a semiconductor package (semiconductor package 11) in accordance with example embodiments. FIG. 17 is an enlarged cross-sectional view illustrating portion ‘E’ in FIG. 16. FIG. 18 is a plan view illustrating flow prevention structures on a first semiconductor chip in portion ‘E’ of FIG. 16. The semiconductor package is substantially the same as the semiconductor package (semiconductor package 10) described with reference to FIG. 1 except for an arrangement of the flow prevention structures. Thus, same reference numerals will be used to refer to the same or like elements and any further repetitive explanation concerning the above elements will be omitted.

Referring to FIGS. 16 to 18, the semiconductor package 11 may include a first flow prevention structure 150 provided on a first semiconductor chip 100. The first flow prevention structure 150 may be within an adhesive layer 300.

In example embodiments, the first flow prevention structure 150 may include a dummy post 152 on a first backside insulation layer 170 of the first semiconductor chip 100. The dummy post 152 may be in a test pad region TA.

The test pad region TA may correspond to a region where a test pad 226 of a second semiconductor chip 200 stacked on the first semiconductor chip 100 is disposed. The first flow prevention structure 150 may include a plurality of dummy posts 152 provided in one test pad region TA. For example, four dummy posts 152 may be provided in one test pad region TA, but not limited thereto.

For example, the dummy post 152 may include a metal such as copper (Cu). A height of the dummy post 152 from the first backside insulation layer 170 may be within a range of 2 μm to 10 μm. In some embodiments, a height of the dummy post 152 is greater than a height of the second bonding pads 180.

Hereinafter, a method of manufacturing the semiconductor package 11 of FIG. 16 will be described.

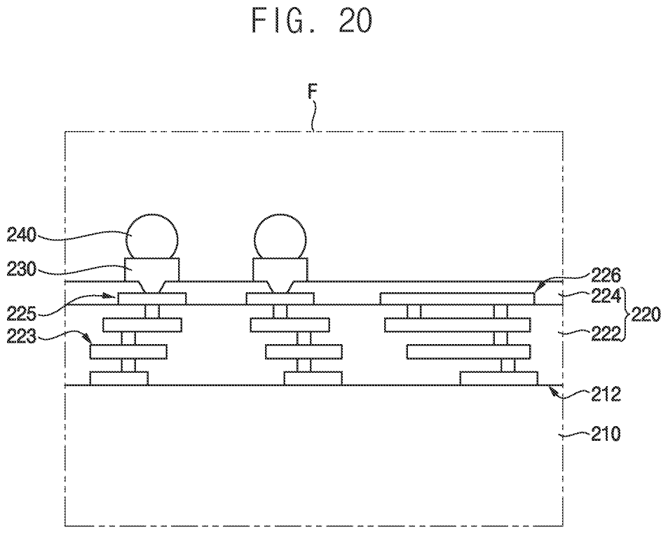

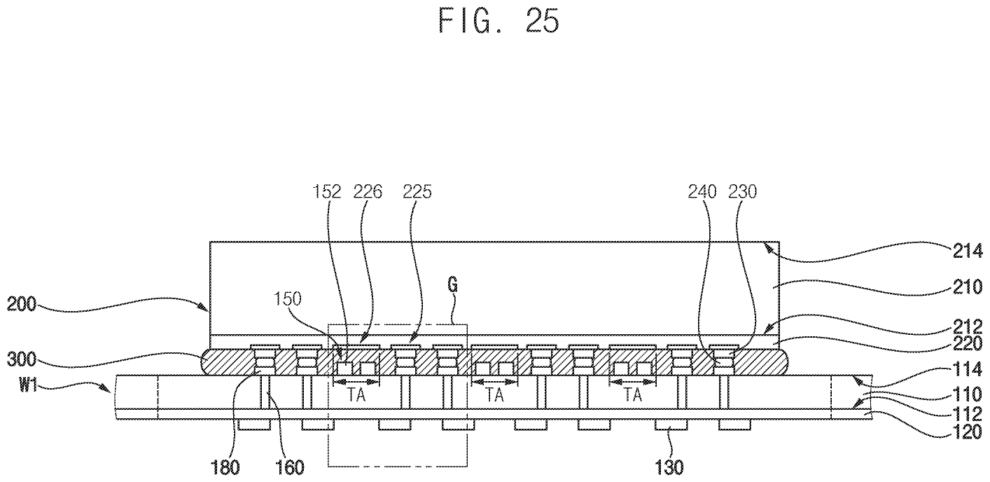

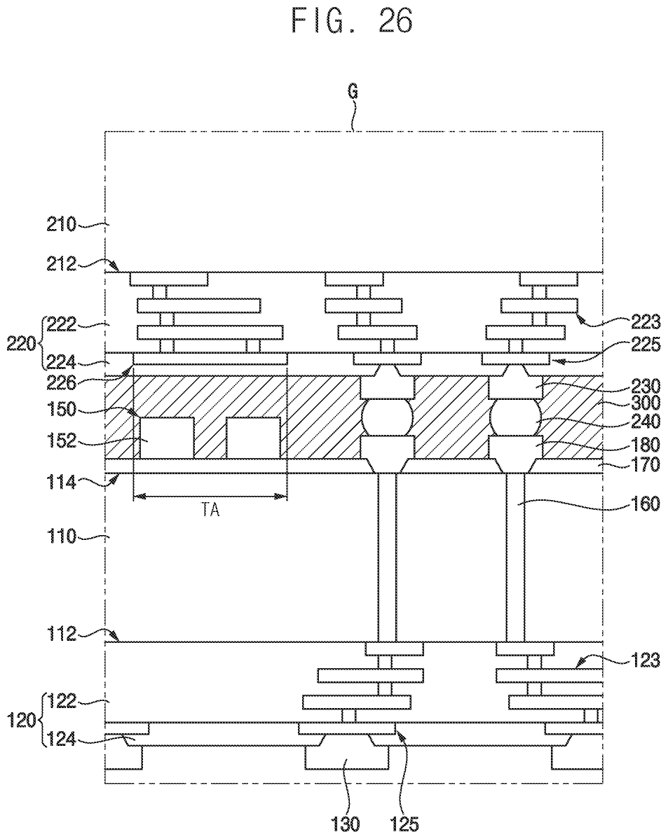

FIGS. 19 to 26 are views illustrating a method of manufacturing a semiconductor package (semiconductor package 11) in accordance with example embodiments. FIG. 20 is an enlarged cross-sectional view illustrating a portion ‘F’ in FIG. 19. FIG. 26 is an enlarged cross-sectional view illustrating portion G′ in FIG. 25.

Referring to FIGS. 19 and 20, third bonding pads 230 may be formed on second redistribution pads 225 on a second wiring layer 220 of a second wafer W2 respectively, and second conductive bumps 240 may be formed on the third bonding pads 230 respectively. The second wiring layer 220 comprises a second metal wiring layer 222 on the second substrate 210 and a protective layer 224 on the second metal wiring layer 222.

Processes the same as or similar to the processes described with reference to FIGS. 4 to 7 may be performed to from the third bonding pads 230 on the second redistribution pads 225 on the second wiring layer 220 of the second wafer W2 respectively, and to form the second conductive bumps 240 on the third bonding pads 230.

In example embodiments, portions of a protective layer 224 may be removed to expose at least portions of the second redistribution pads 225, and the third bonding pads 230 may be formed on the exposed portions of the second redistribution pads 225. At this time, a portion of the protective layer 224 on test pads 226 may not be removed. Thus, the test pads 226 may be covered by the protective layer 224 not to be exposed.

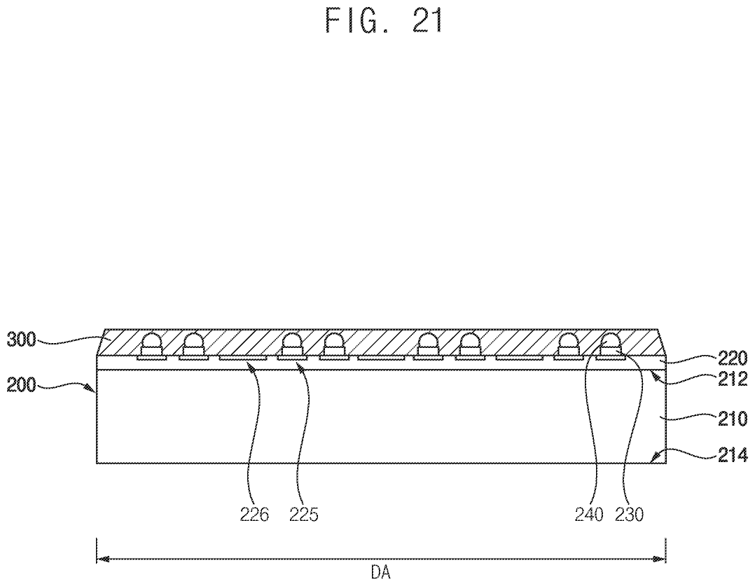

Referring to FIG. 21, the second wafer W2 may be cut along a scribe lane region SA to form an individualized second semiconductor chip 200, and an adhesive layer 300 may be attached on the second semiconductor chip 200. The adhesive layer 300 may be formed on the second wiring layer 220 to cover the second conductive bumps 240.

Processes the same as or similar to the processes described with reference to FIGS. 7 and 8 may be performed to form the adhesive layer 300 on the second semiconductor chip 200 to cover the second conductive bumps 240. The adhesive layer 300 may cover the protective layer 224 in the test pad region TA.

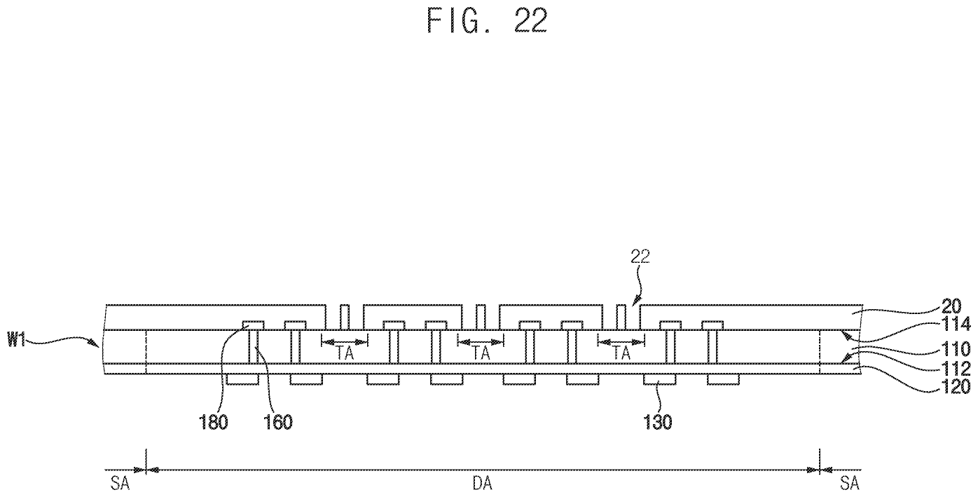

Referring to FIGS. 22 to 24, a first wafer W1 including a plurality of first semiconductor chips (dies) (e.g., first semiconductor chip 100) are formed therein may be provided, and first flow prevention structures 150 may be formed on a backside surface of the first wafer W1 (e.g., second surface 114 of the first substrate 110).

As illustrated in FIG. 22, a photoresist layer may be formed on a first backside insulation layer 170 (see FIG. 26) on a second surface 114 of the first substrate 110 of the first wafer W1, and an exposure process may be performed to form a photoresist pattern 20 having openings 22 that expose portions of the first backside insulation layer 170.

A portion of the first backside insulation layer 170 exposed by the opening 22 may correspond to a test pad region TA where the test pad 226 of the second semiconductor chip 200 to be stacked on the first wafer W1 is disposed.

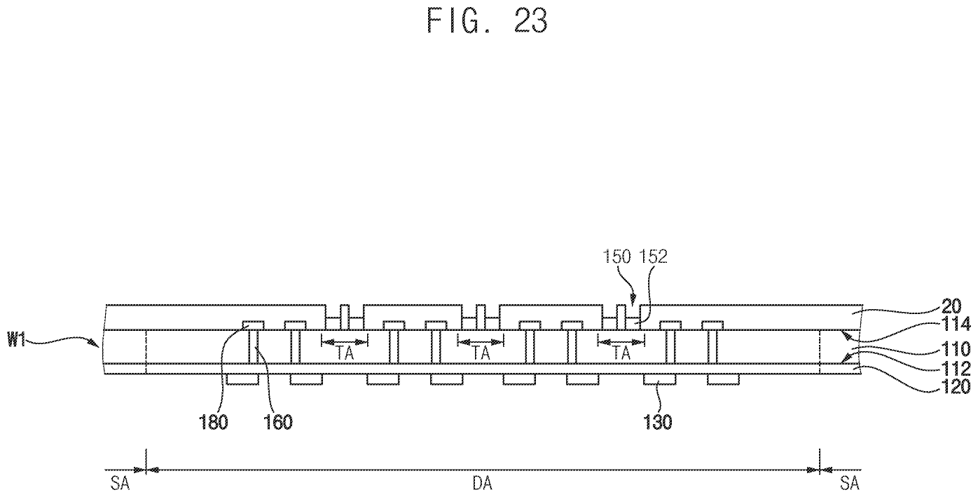

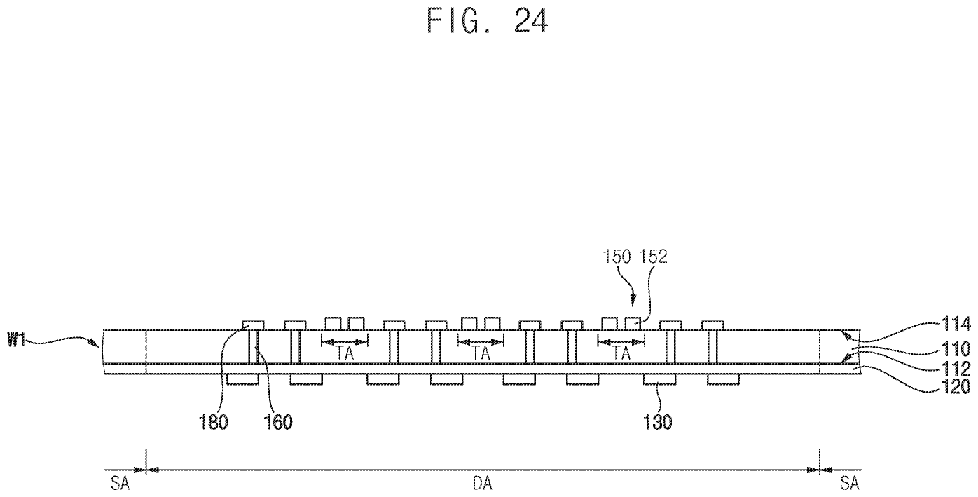

As illustrated in FIGS. 23 and 24, the openings 22 of the photoresist pattern 20 may be filled up with, for example, a conductive material to form a dummy post 152, and the photoresist pattern 20 may be removed from the first wafer W1. Accordingly, the first flow prevention structure 150 including the dummy post 152 may be formed on the test pad region TA on the first backside insulation layer 170.

For example, the dummy posts 152 may be formed by a plating process. Alternatively, the dummy posts may be formed by a screen printing method, a deposition method, or the like. The dummy post 152 may include, for example, a metal such as copper (Cu). A height of the dummy post 152 from the first backside insulation layer 170 may be within a range of 2 μm to 10 μm.

A plurality of the dummy posts 152 may be formed in one test pad region TA. For example, four dummy posts 152 may be formed in one test pad region TA. Alternatively, one dummy post 152 may be formed in one test pad region TA.

Referring to FIGS. 25 and 26, the second semiconductor chip 200 may be stacked on the first wafer W1. The second semiconductor chip 200 may be mounted on the first wafer W1 via the second conductive bumps 240.

Processes the same as or similar to the processes described with reference to FIGS. 11 and 12 may be performed to stack the second semiconductor chip 200 on the first wafer W1. The second semiconductor chips 200 may be disposed on the first wafer W1 to correspond to die regions DA respectively. The second semiconductor chip 200 may be attached on the first wafer W1 using the adhesive layer 300. The first surface 212 of the second substrate 210 of the second semiconductor chip 200 may face the first wafer W1.

A thermal compression process may be performed at a predetermined temperature (eg, about 400° C. or less) to attach the second semiconductor chip 200 on the first wafer W1. By the thermal compression process, the second semiconductor chip 200 and the first wafer W1 may be bonded to each other. The embodiments of the bonding method, however, are not limited to the above noted thermal compression process.

In the thermal compression process, the non-conductive film, which will be the adhesive layer 300 by the following processes, may be liquefied and have fluidity, and may flow between the second semiconductor chip 200 and the first wafer W1. The first flow prevention structure 150 having the dummy posts 152 may be formed on the test pad region TA between the second conductive bumps 240. Accordingly, solder sweep due to the flow of the non-conductive film may be prevented to thereby prevent a short circuit defect.

Then, processes the same as or similar to the processes described with reference to FIGS. 13 to 15 may be performed to complete the semiconductor package 11 of FIG. 16.

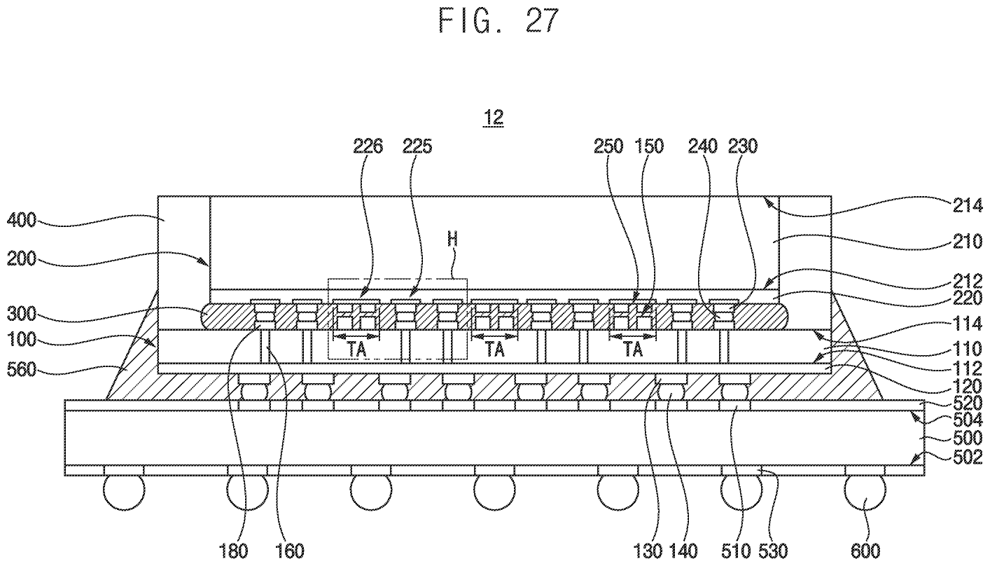

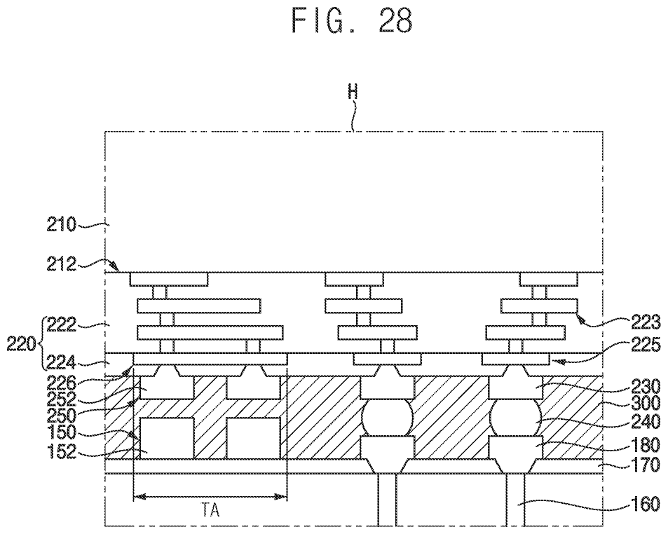

FIG. 27 is a cross-sectional view illustrating a semiconductor package (semiconductor package 12) in accordance with example embodiments. FIG. 28 is an enlarged cross-sectional view illustrating portion ‘H’ in FIG. 27. The semiconductor package may be substantially the same as the semiconductor package (semiconductor package 10) described with reference to FIG. 1 except for a configuration of a flow prevention structure. Thus, same reference numerals will be used to refer to the same or like elements and any further repetitive explanation concerning the above elements will be omitted.

Referring to FIGS. 27 and 28, a flow prevention structure of a semiconductor package 12 may include a first flow prevention structure 150 provided on a first semiconductor chip 100 and a second flow prevention structure 250 provided on a second semiconductor chip 200 in an adhesive layer 300.

In example embodiments, the first flow prevention structure 150 may include a dummy post 152 on a first backside insulation layer 170 of the first semiconductor chip 100. The dummy post 152 may be in a test pad region TA.

The test pad region TA may correspond to a region where a test pad 226 of the second semiconductor chip 200 stacked on the first semiconductor chip 100 is disposed. The first flow prevention structure 150 may include a plurality of dummy posts 152 provided in one test pad region TA. For example, four dummy posts 152 may be provided in one test pad region TA.

In example embodiments, the second flow prevention structure 250 may include a dummy pad 252 provided on the test pad 226. The second flow prevention structure 250 may include a plurality of dummy pads 252 provided on one test pad 226. For example, four dummy pads 252 may be disposed on one test pad 226.

The dummy posts 152 of the first flow prevention structure 150 and the dummy pads 252 of the second flow prevention structure 250 may overlap each other in a vertical direction perpendicular to the first surface 112 and/or second surface 114 of the first substrate 110. Alternatively, the dummy posts 152 of the first flow prevention structure 150 and the dummy pads 252 of the second flow prevention structure 250 may be arranged to cross each other or to partially overlap each other in the vertical direction.

The dummy posts 152 of the first flow prevention structure 150 and the dummy pads 252 of the second flow prevention structure 250 may be spaced apart from each other in the vertical direction. Alternatively, the dummy posts 152 of the first flow prevention structure 150 and the dummy pads 252 of the second flow prevention structure 250 may contact each other.

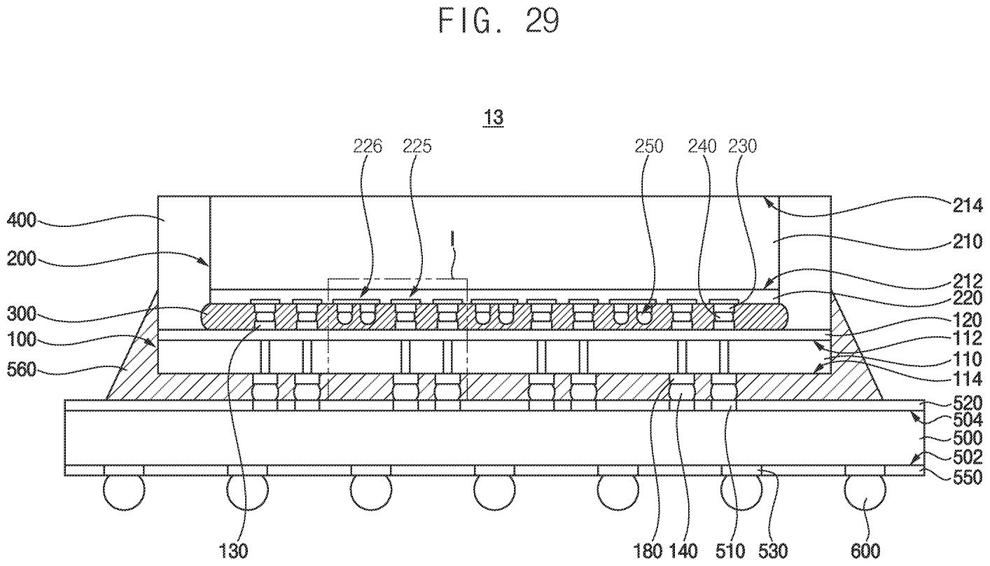

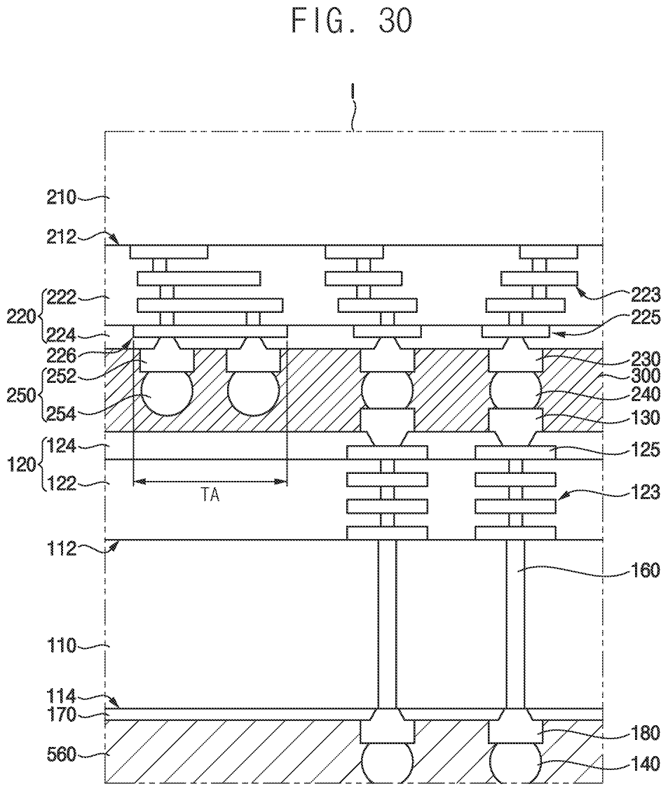

FIG. 29 is a cross-sectional view illustrating a semiconductor package (semiconductor package 13) in accordance with example embodiments. FIG. 30 is an enlarged cross-sectional view illustrating portion ‘I’ in FIG. 29. The semiconductor package is substantially the same as the semiconductor package (semiconductor package 10) described with reference to FIG. 1 except for an arrangement relationship between first and second semiconductor chips. Thus, same reference numerals will be used to refer to the same or like elements and any further repetitive explanation concerning the above elements will be omitted.

Referring to FIGS. 29 and 30, a first semiconductor chip 100 and a second semiconductor chip 200 of the semiconductor package 13 may be arranged such that a front surface (e.g., first surface 112 of the first substrate 110) of the first semiconductor chip 100 and a front surface (e.g., first surface 212 of the second substrate 210) of the second semiconductor chip 200 face each other.

In example embodiments, a first wiring layer 120 of the first semiconductor chip 100 may include a first metal wiring layer 122 and a first passivation layer 124 sequentially stacked on a first surface 112 of a first substrate 110. The first metal wiring layer 122 may include a plurality of insulating layers, first upper wirings 123 in the insulating layers, and first redistribution pads 125 as uppermost wirings. The first passivation layer 124 may be formed on the first metal wiring layer 122 and may cover the first redistribution pads 125. The first redistribution pads 125 may be electrically connected to circuit elements through the first upper wirings 123.

A first bonding pad 130 may be provided on at least a portion of the first redistribution pad 125. The first bonding pad 130 may be electrically connected to the first redistribution pad 125.

In example embodiments, a first surface 212 of a second substrate 210 of the second semiconductor chip 200 may face the first surface 112 of the first substrate 110 of the first semiconductor chip 100. A second conductive bump 240 of the second semiconductor chip 200 may be on (e.g., bonded to) the first bonding pad 130 of the first semiconductor chip 100.

Accordingly, the second semiconductor chip 200 may be electrically connected to the first semiconductor chip 100 by the second conductive bump 240. The second semiconductor chip 200 may be electrically connected to an external device through the second conductive bump 240 and a through electrode 160.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, high band width memory (HBM) devices, or non-volatile memory devices such as flash memory devices, phase change random access memory (PRAM) devices, magnetoresistive random access memory (MRAM) devices, resistive random-access memory (ReRAM) devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

It should also be noted that in some alternate implementations, the steps of the method of manufacturing herein may occur out of the order. For example, two steps described in succession may in fact be executed substantially concurrently or the steps may sometimes be executed in the reverse order. Moreover, the steps of method may be separated into multiple steps and/or may be at least partially integrated. Finally, other steps may be added/inserted between the steps that are illustrated, and/or the steps may be omitted without departing from the scope of the present invention.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. As used herein, the term “and/or” includes any and all combinations of one or more of the associated listed items. Moreover, the symbol “/” will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

What is claimed is:

1. A semiconductor package, comprising:
a first semiconductor chip including:
a first substrate comprising a second surface;
a plurality of through electrodes extending in the first substrate; and
first bonding pads on the second surface of the first substrate,
wherein the first bonding pads are electrically connected to the plurality of through electrodes;
a second semiconductor chip including:
a second substrate comprising a first surface;
a second wiring layer on the first surface of the second substrate;
redistribution pads in the second wiring layer;
second bonding pads on the redistribution pads;
first conductive bumps between the first bonding pads and the second bonding pads; and
a test pad region between the first conductive bumps, wherein the test pad region comprises a test pad in the second wiring layer,
wherein the second semiconductor chip is stacked on the first semiconductor chip via the first conductive bumps;
an adhesive layer between the first semiconductor chip and the second semiconductor chip, wherein the adhesive layer is disposed between the first conductive bumps; and
flow prevention structures in the adhesive layer, wherein the flow prevention structures are disposed in the test pad region.

2. The semiconductor package of claim 1, wherein the adhesive layer includes a non-conductive film (NCF).

3. The semiconductor package of claim 1, wherein the flow prevention structures include a dummy pad on the test pad and a dummy bump on the dummy pad.

4. The semiconductor package of claim 3, wherein the dummy bump includes a same material as the first conductive bumps.

5. The semiconductor package of claim 3, wherein the dummy pad includes a same material as the second bonding pads.

6. The semiconductor package of claim 1, further comprising: a first backside insulation layer on the second surface of the first substrate,
wherein the flow prevention structures include a dummy post on the first backside insulation layer.

7. The semiconductor package of claim 6, wherein the flow prevention structures further include a dummy pad on the test pad of the second semiconductor chip,
wherein the dummy pad and the dummy post overlap with each other in a vertical direction perpendicular to the second surface of the first substrate.

8. The semiconductor package of claim 6, wherein the dummy post has a height greater than a height of the first bonding pads.

9. The semiconductor package of claim 8, wherein a height of the dummy post from the first backside insulation layer is within a range of 2 μm to 10 μm.

10. The semiconductor package of claim 1, further comprising:
a package substrate, and
wherein the first semiconductor chip is mounted on the package substrate via second conductive bumps.

11. A semiconductor package, comprising:
a first semiconductor chip including:
a first substrate having a first surface and a second surface opposite to the first surface;
a plurality of through electrodes penetrating the first substrate;
first bonding pads on the first surface, wherein the first bonding pads are electrically connected to the plurality of through electrodes; and
second bonding pads on the second surface, wherein the second bonding pads are electrically connected to the plurality of through electrodes;
a second semiconductor chip including:
a second substrate having a third surface and a fourth surface opposite to the third surface;
a second wiring layer on the third surface of the second substrate; and
third bonding pads on the second wiring layer,
wherein the second semiconductor chip is on the second surface of the first substrate,
wherein the second wiring layer includes redistribution pads and test pads, and
wherein the third bonding pads are on the redistribution pads;
conductive bumps between the first semiconductor chip and the second semiconductor chip and electrically connecting the second bonding pads and the third bonding pads;
an adhesive layer between the first semiconductor chip and the second semiconductor chip, wherein the adhesive layer is in a space between the conductive bumps; and
flow prevention structures in the adhesive layer,
wherein the flow prevention structures overlap the test pads viewed from a plan view.

12. The semiconductor package of claim 11, wherein the adhesive layer includes a non-conductive film (NCF).

13. The semiconductor package of claim 11, wherein the flow prevention structures include a dummy pad on the test pads and a dummy bump on the dummy pad.

14. The semiconductor package of claim 13, wherein the dummy bump includes a same material as the conductive bumps.

15. The semiconductor package of claim 14, wherein the dummy bump has a diameter same as a diameter of the conductive bumps.

16. The semiconductor package of claim 13, wherein the dummy pad includes a same material as the third bonding pads.

17. The semiconductor package of claim 11, wherein the flow prevention structures include a dummy post on the first semiconductor chip.

18. The semiconductor package of claim 17, wherein the flow prevention structures further include a dummy pad on the test pads, and
wherein the dummy pad and the dummy post overlap with each other in a vertical direction perpendicular to the second surface of the first substrate.

19. The semiconductor package of claim 17, wherein the dummy post has a height greater than a height of the second bonding pads.

20. A semiconductor package, comprising:
a package substrate;
a first semiconductor chip including a first substrate having a first surface and a second surface opposite to the first surface, a plurality of through electrodes penetrating the first substrate, first bonding pads on the first surface and electrically connected to the plurality of through electrodes, and second bonding pads on the second surface and electrically connected to the plurality of through electrodes, the first semiconductor chip being stacked on the package substrate via first conductive bumps that are on the first bonding pads;
a second semiconductor chip including a second substrate having a third surface and a fourth surface opposite to the third surface, a second wiring layer having redistribution pads and test pads on the third surface of the second substrate, and third bonding pads on the redistribution pads, the second semiconductor chip being stacked on the first semiconductor chip via second conductive bumps that are on the third bonding pads,
an adhesive layer between the first semiconductor chip and the second semiconductor chip to fill a space between the second conductive bumps; and
flow prevention structures in the adhesive layer,
wherein the flow prevention structures are arranged on at least one of the first semiconductor chip and the second semiconductor chip to overlap the test pads when viewed from a plan view.
